(19) United States
(12) Patent Application Publication
(10) Pub. No.: US 2024/0072151 A1
(43) Pub. Date: Feb. 29, 2024

(54) SEMICONDUCTOR DEVICE AND METHOD OF MANUFACTURING THE SEMICONDUCTOR DEVICE

(71) Applicant: Samsung Electronics Co., Ltd., Suwon-si (KR)

(72) Inventors: Dukhyun CHOE, Suwon-si (KR); Jinseong HEO, Seoul (KR); Yunseong LEE, Osan-si (KR); Sanghyun JO, Seoul (KR)

(73) Assignee: Samsung Electronics Co., Ltd., Suwon-si (KR)

(21) Appl. No.: 18/502,545

(22) Filed: Nov. 6, 2023

Related U.S. Application Data
(63) Continuation-in-part of application No. 17/496,300, filed on Oct. 7, 2021, now Pat. No. 11,843,037.

(30) Foreign Application Priority Data
Mar. 19, 2021 (KR) 10-2021-0036079
Mar. 29, 2021 (KR) 10-2021-0040542

(51) Int. Cl. H01L 29/51; H01L 29/78

(52) U.S. Cl. CPC H01L 29/516; H01L 29/78391

(57) ABSTRACT

Provided is a semiconductor device including a substrate on which a channel layer is provided, an insulation layer provided on the substrate, a ferroelectric layer provided on the insulation layer, a fixed charge region provided in the ferroelectric layer and containing charges of a predetermined polarity, and a gate provided on the ferroelectric layer. An absolute value of a charge density in the fixed charge region is greater than 0 and less than 5 μC/cm².

### CROSS-REFERENCE TO RELATED APPLICATION

This application is a continuation-in-part to U.S. application Ser. No. 17/496,300, filed Oct. 7, 2021, which is based on and claims priority under 35 U.S.C. §119 to Korean Patent Application Nos. 10-2021-0036079, filed on Mar. 19, 2021, and 10-2021-0040542, filed on Mar. 29, 2021, in the Korean Intellectual Property Office, the disclosures of each of which are incorporated by reference herein in their entirety.

### BACKGROUND

### 1. Field

The present disclosure relates to a semiconductor device and a method of manufacturing the semiconductor device.

### 2. Description of the Related Art

Existing silicon-based transistors have limitations in improving the operating characteristics and scaling down. For example, when an operating voltage and current characteristics are measured in the case of existing silicon-based transistors, a subthreshold swing (SS) value is determined according to the equation below, and it is known that the SS value is limited to about 60 mV/dec.

$$SS = \frac{{k}_{B} T}{q} ln ( 10 ) ( 1 + \frac{{C}_{D}}{{C}_{ins}} )$$

In this equation, k_{B} indicates a Boltzmann constant, T indicates an absolute temperature, q indicates an elementary charge, C_{D} indicates a capacitance of a depletion layer, and Cᵢₙₛ indicates a capacitance of a gate insulator.

With a decrease in the size of a transistor, a power density increases because it is difficult to lower the operating voltage to about 0.8 V or less. Accordingly, there is a limit in scaling down a device.

### SUMMARY

Provided are a semiconductor device and a method of manufacturing the semiconductor device.

Additional aspects will be set forth in part in the description which follows and, in part, will be apparent from the description, or may be learned by practice of the presented embodiments of the disclosure.

According to an aspect of an embodiment, a semiconductor device includes a substrate on which a channel layer is provided; an insulation layer provided on the substrate; a ferroelectric layer provided on the insulation layer; a fixed charge region provided in the ferroelectric layer and containing charges of a predetermined polarity; and a gate provided on the ferroelectric layer, wherein an absolute value of a charge density in the fixed charge region is greater than 0 and less than 5 μC/cm₂.

The absolute value of the charge density in the fixed charge region may be greater than 2 μC/cm² and less than 3 μC/cm².

A thickness of the fixed charge region may be 1 Å to 10 Å.

The ferroelectric layer may have a dopant concentration gradient in its thickness direction, and the fixed charge region may be defined by a dopant concentration collecting region in the ferroelectric layer.

The dopant may include at least one selected from Al, P, Ca, Sc, V, Cr, Sr, Y, Nb, Mo, Tm, Yb, Lu, Ta, W, B, and Mg.

The ferroelectric layer may have an oxygen vacancy concentration gradient in its thickness direction, and the fixed charge region may be defined by an oxygen vacancy concentration collecting region in the ferroelectric layer.

The fixed charge region may be disposed on an interface between the ferroelectric layer and the insulation layer.

The fixed charge region may be disposed within the ferroelectric layer. The fixed charge region may be disposed adjacent to the interface between the ferroelectric layer and the insulation layer.

The fixed charge region may have a negative (−) charge density in a semiconductor device of a PMOS structure, and have a positive (+) charge density in a semiconductor device of an NMOS structure.

The ferroelectric layer may include a fluorite-based material, a perovskite, aluminum nitride, or magnesium oxide.

The channel layer may include at least one of Si, Ge, SiGe, a Groups III-V semiconductor, an oxide semiconductor, a nitride semiconductor, an oxynitride semiconductor, a two-dimensional (2D) material, quantum dots, and an organic semiconductor.

A threshold voltage of the semiconductor device may be controlled by adjusting a work function of the gate.

According to an aspect of another embodiment, a semiconductor device includes a substrate on which a channel layer is provided; an insulation layer provided on the substrate; a ferroelectric layer provided on the insulation layer; a dopant concentration collecting region provided in the ferroelectric layer; and a gate provided on the ferroelectric layer, wherein a dopant concentration in the dopant concentration collecting region is greater than 0 and less than 3.1×10¹³/cm².

The ferroelectric layer may have a dopant concentration gradient in its thickness direction.

The dopant may include at least one selected from Al, P, Ca, Sc, V, Cr, Sr, Y, Nb, Mo, Tm, Yb, Lu, Ta, W, B, and Mg.

The dopant concentration collecting region may be disposed on an interface between the ferroelectric layer and the insulation layer or within the ferroelectric layer.

According to an aspect of another embodiment, a semiconductor device includes a substrate on which a channel layer is provided; an insulation layer provided on the substrate; a ferroelectric layer provided on the insulation layer; an oxygen vacancy concentration collecting region provided in the ferroelectric layer; and a gate provided on the ferroelectric layer, wherein an oxygen vacancy concentration in the oxygen vacancy concentration collecting region is greater than 0 and less than 1.55×10¹³/cm².

The ferroelectric layer may have an oxygen vacancy concentration gradient in its thickness direction.

The oxygen vacancy concentration collecting region may be disposed on an interface between the ferroelectric layer and the insulation layer or within the ferroelectric layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a general semiconductor device including ferroelectrics;

FIG. 2 is a charge (Q)-electric field (E_{FE}) graph of an “S” curved shape appearing when a charge (or polarization value) Q of ferroelectrics and an electric field E_{FE} applied to ferroelectrics were measured under a specific condition according to a Landau model that describes ferroelectrics;

FIG. 3 is a graph for explaining an effect where a subthreshold swing (SS) feature of the semiconductor device of FIG. 1 is improved;

FIG. 4 illustrates a correlation between a state of the semiconductor device of FIG. 1 and a negative capacitance region, through the Q-E_{FE} graph of the “S” curved shape of the ferroelectrics of FIG. 2;

FIG. 5 is a schematic cross-sectional view of a semiconductor device according to an embodiment;

FIGS. 6A through 6C illustrate a correlation between a state of the semiconductor device of FIG. 5 and a negative capacitance region according to a charge density of a fixed charge region in the semiconductor device of FIG. 5;

FIG. 7 is a schematic cross-sectional view of a semiconductor device according to another embodiment;

FIGS. 8A through 8D are views for explaining a method of a manufacturing a semiconductor device, according to an embodiment;

FIG. 9 is a schematic cross-sectional view of a semiconductor device according to another embodiment;

FIG. 10 is a schematic cross-sectional view of a semiconductor device according to another embodiment;

FIGS. 11 and 12 are views of a semiconductor device according to another embodiment; and

FIGS. 13 and 14 are views of a semiconductor device according to another embodiment.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Exemplary embodiments will now be described more fully with reference to the accompanying drawings. Like reference numerals in the drawings denote like elements, and, in the drawings, the sizes of elements may be exaggerated for clarity and for convenience of explanation. In this regard, the present embodiments may have different forms and should not be construed as being limited to the descriptions set forth herein.

When a layer is referred to as being “”on” another layer or substrate, it can be directly on/below/on the left side of/on the right side of the other layer or substrate, or intervening layers may also be present. An expression used in the singular encompasses the expression of the plural, unless it has a clearly different meaning in the context. The terms “comprises” and/or “comprising” or “includes” and/or “including” when used in this specification, specify the presence of stated elements, but do not preclude the presence or addition of one or more other elements.

The use of the terms “a” and “an” and “the” and similar referents are to be construed to cover both the singular and the plural. The operations that constitute a method described herein can be performed in any suitable order unless otherwise indicated herein or otherwise clearly contradicted by context, but embodiments are not limited to the stated order.

The terms “unit”, “-er (-or)”, and “module” when used in this specification refers to a unit in which at least one function or operation is performed, and may be implemented as hardware, software, or a combination of hardware and software.

The connecting lines, or connectors shown in the various figures presented are intended to represent exemplary functional relationships and/or physical or logical couplings between the various elements. It should be noted that many alternative or additional functional relationships, physical connections or logical connections may be present in a practical device.

The use of any and all examples, or exemplary language provided herein, is intended merely to better illuminate the inventive concept and does not pose a limitation on the scope of the present disclosure unless otherwise claimed.

FIG. 1 is a schematic cross-sectional view of a general semiconductor device including ferroelectrics. A semiconductor device 100 of FIG. 1 may be a ferroelectric field effect transistor (FeFET).

Referring to FIG. 1, the semiconductor device 100 includes a substrate 110, an insulation layer 130, a ferroelectric layer 140, and a gate 150. A channel layer 115 is located in an upper portion of the substrate 110 and is integrally formed with the substrate 110. The channel layer 115 may be provided in an upper portion of the substrate 110 that faces the gate 150, and a source 121 and a drain 122 may be provided on both sides of the channel layer 115, respectively.

The source 121 may be electrically connected to one side of the channel layer 115, and the drain 122 may be electrically connected to the other side of the channel layer 115. The source and drain 121 and 122 may be formed by implanting impurities into different regions of the substrate 110, and a region of the substrate 110 between the source 121 and the drain 122 may be defined as the channel layer 115. The substrate 110 integrally formed with the channel layer 115 may be, for example, a semiconductor substrate including Si, Ge, SiGe, or Group III-V semiconductor.

The insulation layer 130, the ferroelectric layer 140, and the gate 150 are sequentially stacked on the substrate 110. The insulation layer 130 is provided on the substrate 110(in detail, the channel layer 115). The insulation layer 130 may include, for example, silicon oxide, silicon nitride, or the like, but embodiments are not limited thereto.

The ferroelectric layer 140 is provided on the insulation layer 130. The ferroelectric layer 140 may include ferroelectrics, such as a fluorite-based material, a perovskite, aluminum nitride, or magnesium oxide. The ferroelectrics have a spontaneous dipole (electric dipole), namely, spontaneous polarization, because a charge distribution within a unit cell is non-centrosymmetric in a crystallized material structure. The ferroelectrics also have a remnant polarization due to a dipole even in a state where there are no external electric fields. In the ferroelectrics, a direction of polarization may be switched in units of domain by an external electric field.

The gate 150 is provided on the ferroelectric layer 140. The gate 150 may be disposed opposite to the channel layer 115 of the substrate 110. The gate 150 may include, for example, a conductive metal.

In the semiconductor device 100 of FIG. 1, as will be described later, the ferroelectric layer 140 is formed between the gate 150 and the insulation layer 130, and thus a subthreshold swing (SS) of the semiconductor device 100 may be lowered due to voltage amplification according to a negative capacitance effect.

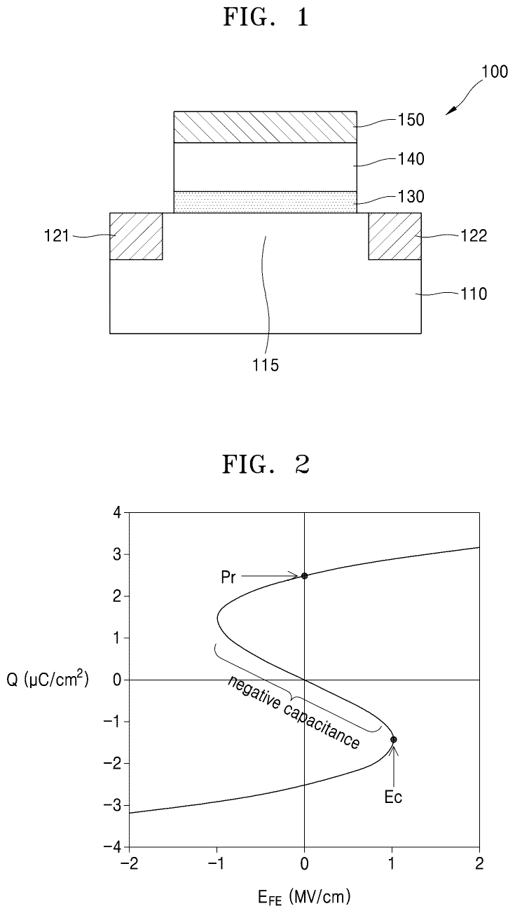

FIG. 2 is a charge (Q)-electric field (E_{FE}) graph of an “S” curved shape appearing when a charge (or polarization value)Q of ferroelectrics and an electric field E_{FE} applied to ferroelectrics were measured under a specific condition according to a Landau model that describes ferroelectrics. In FIG. 2, “Pᵣ” indicates a remnant polarization referring to a polarization value within ferroelectrics when no electric fields are applied, and “E_{c}” indicates a coersive electric field referring to the size of a critical electric field capable of changing the direction of polarization.

Referring to FIG. 2, the capacitance in ferroelectrics has a value proportional to the inclination of the Q-E_{FE} graph. In this case, a negative capacitance region having a negative (−) inclination exists in the Q-E_{FE} graph of the “S” curved shape, and voltage amplification occurs when a domain within ferroelectrics is switched due to a negative capacitance effect occurring in the negative capacitance region. Accordingly, the SS may be lowered.

As the remnant polarization Pr or the coersive electric field E_{C} increases in the Q-E_{FE} graph of the “S” curved shape, the negative capacitance effect may be increased. Accordingly, performance of the semiconductor device may be more improved by further lowering the SS. As such, the physical property of ferroelectrics, such as the remnant polarization Pr or the coersive electric field E_{C}, is improved by adjusting a method of depositing ferroelectrics or a method of annealing ferroelectrics, leading to an increase in the negative capacitance effect.

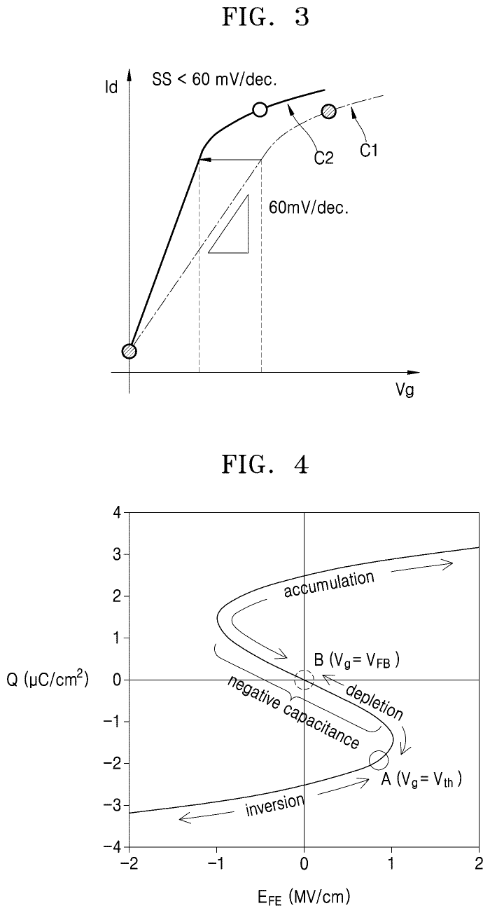

FIG. 3 is a graph for explaining an effect where the SS feature of the semiconductor device 100 of FIG. 1 is improved. In FIG. 3, “C1” illustrates an operating voltage Vg and a current Id of an existing silicon-based field effect transistor, and “C2B” illustrates an operating voltage Vg and a current Id of the semiconductor device (ferroelectric field effect transistor) 100 of FIG. 1.

Referring to FIG. 3, it is known that the SS of an existing silicon-based transistor is limited to about 60 mV/dec. However, in the semiconductor device 100 of FIG. 1, voltage amplification may occur due to a negative capacitance effect according to the use of the ferroelectric layer 140, and thus the swing SS may be lowered to 60 mV/dec or less. Therefore, low-power driving is possible by amplifying a voltage that is applied to the semiconductor device 100, and the scale of the semiconductor device 100 may be lowered.

FIG. 4 illustrates a correlation between a state of the semiconductor device of FIG. 1 and a negative capacitance region, through a Q-E_{FE} graph of the “S” curved shape of the semiconductor device of FIG. 1. In FIG. 4, a point “A” indicates a location of a threshold voltage Vₜₕ, and a point “B” indicates a location of a planarization voltage V_{FB} that is applied to the gate 150 to offset band bending of a semiconductor.

Referring to FIG. 4, when a gate voltage V_{g} is less than the planarization voltage V_{FB}, the semiconductor device 100 (in detail, the channel layer 115) enters an accumulation state, and, when the gate voltage V_{g} is greater than the planarization voltage V_{FB} and less than the threshold voltage Vₜₕ, the semiconductor device 100 enters a depletion state. When the gate voltage V_{g} is greater than the threshold voltage Vₜₕ, the semiconductor device 100 enters an inversion state.

In the semiconductor device 100 of FIG. 1, as shown in FIG. 4, the negative capacitance effect occurs in the accumulation state and the depletion sate of the semiconductor device 100. However, in this case, performance of the semiconductor device 100 may not be more improved because voltage amplification is not large, than a case where the negative capacitance effect occurs in the inversion state of the semiconductor device 100.

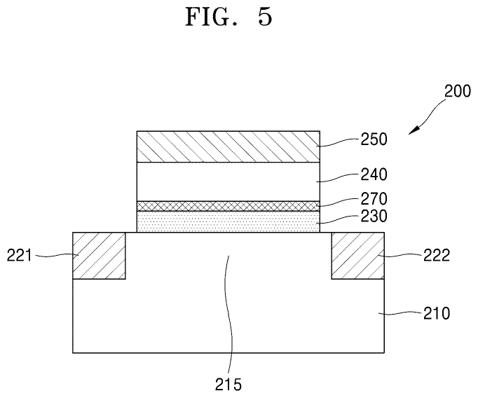

FIG. 5 is a schematic cross-sectional view of a semiconductor device 200 according to an embodiment. The semiconductor device 200 of FIG. 5 may be a ferroelectric field effect transistor (FeFET). For example, the semiconductor device 200 may be a logic semiconductor device or a memory semiconductor device.

Referring to FIG. 5, the semiconductor device 200 includes a substrate 210, an insulation layer 230, a fixed charge region 270, a ferroelectric layer 240, and a gate 250. A channel layer 215 is located in an upper portion of the substrate 210 and is integrally formed with the substrate 210. The channel layer 215 may be provided in an upper portion of the substrate 210 that faces the gate 250, and a source 221 and a drain 222 may be provided on both sides of the channel layer 215, respectively.

The source 221 may be electrically connected to one side of the channel layer 215, and the drain 222 may be electrically connected to the other side of the channel layer 215. The source and drain 221 and 222 may be formed by implanting impurities into different regions of the substrate 210, and a region of the substrate 210 between the source 221 and the drain 222 may be defined as the channel layer 215.

The substrate 210 and the channel layer 215 may include Si. However, this is merely an example, and the substrate 210 and the channel layer 215 may include, for example, Ge, SiGe, or Group III-V semiconductor. However, embodiments of the disclosure are not limited thereto. As will be described later, the channel layer 215 may not be formed as a portion of the substrate 210 but may be formed a material layer separate from the substrate 210.

When a p-type semiconductor substrate is used as the substrate 210 and the source and drain 221 and 222 include n-type impurities, a semiconductor device 200 of a NMOS structure may be implemented. When an n-type semiconductor substrate is used as the substrate 210 and the source and drain 221 and 222 include p-type impurities, a semiconductor device 200 of a PMOS structure may be implemented.

The insulation layer 230, the fixed charge region 270, the ferroelectric layer 240, and the gate 250 are sequentially stacked on the substrate 210. The insulation layer 230 is provided on the substrate 210 (in detail, the channel layer 215). The insulation layer 230 may include a paraelectric material or a high-k material. For example, the insulation layer 230 may include silicon oxide, silicon nitride, aluminum oxide, hafnium oxide, or zirconium oxide or may include a 2D insulator such as h-BN. However, this is merely an example.

The fixed charge region 270 and the ferroelectric layer 240 are sequentially provided on the insulation layer 230. The ferroelectric layer 240 may include ferroelectrics, such as a fluorite-based material, a perovskite, aluminum nitride, or magnesium oxide. The perovskite may include, for example, PZT, BaTiO₃, or PbTiO₃. The fluorite-based material may include, for example, at least one oxide selected from Hf, Si, Al, Zr, Y, La, Gd, and Sr.

For example, the ferroelectric layer 240 may include at least one of HfO, ZrO, and HfZrO. HfO, ZrO or HfZrO constituting the ferroelectric layer 240 may have a crystal structure of an orthorhombic crystal system. On the other hand, HfO, ZrO or HfZrO constituting the high-k material may have a crystal structure of a monoclinic crystal system. The aforementioned materials are only an example, and various other materials may be used to form the ferroelectric layer 240.

The ferroelectric layer 240 may have a thickness of about 10 Å or greater. For example, in a logic semiconductor device, a ferroelectric layer may have a thickness of about 10 Å to 20 Å, but embodiments are not limited thereto.

The fixed charge region 270 including charges of a predetermined polarity may be provided between the insulation layer 230 and the ferroelectric layer 240. The fixed charge region 270 may have a positive (+) polarity or a negative (−) polarity.

As will be described later, the fixed charge region 270 is provided on an interface between the insulation layer 230 and the ferroelectric layer 240 and thus adjusts the negative capacitance region due to the level of a charge density of the fixed charge region 270, thereby generating a negative capacitance effect in the inversion state of the semiconductor device 200 (in detail, the channel layer 215). To this end, an absolute value of the charge density in the fixed charge region 270 may be greater than 0 and less than 5 μC/cm². For example, the absolute value of the charge density in the fixed charge region 270 may be greater than 2 μC/cm² and less than 3 μC/cm².

The fixed charge region 270 may have, for example, a predetermined positive (+) charge density or a predetermined negative (−) charge density. In detail, the fixed charge region 270 of the semiconductor device 200 of a PMOS structure may have a negative (−) charge density. The negative (−) charge density may be greater than about −5 μC/cm² and less than 0. For example, the negative (−) charge density may be greater than −3 μC/cm² and less than −2 μC/cm². The fixed charge region 270 of the semiconductor device 200 of an NMOS structure may have a positive (+) charge density. The positive (+) charge density may be greater than 0 and less than +5 μC/cm². For example, the positive (+) charge density may be greater than +2 μC/cm² and less than +3 μC/cm². The fixed charge region 270 may have a thickness of approximately 1 Å to 10 Å. For example, the fixed charge region 270 may have a thickness of approximately 1 Å to 5 Å (e,g., 1 Å to 3 Å). However, embodiments are not limited thereto

As will be described later, the fixed charge region 270 may be formed by depositing a dopant including charges of a predetermined polarity on a surface of the insulation layer 230. The dopant may include at least one selected from, for example, Al, P, Ca, Sc, V, Cr, Sr, Y, Nb, Mo, Tm, Yb, Lu, Ta, W, B, and Mg. However, embodiments are not limited thereto. In this case, a dopant concentration in the fixed charge region 270 may be greater than 0 and less than 3.1×10¹³/cm². The dopant concentration refers to the number of dopant particles per unit area.

The fixed charge region 270 may be formed by creating oxygen vacancy by treating the surface of the insulation layer 230. In this case, an oxygen vacancy concentration in the fixed charge region 270 may be greater than 0 and less than 1.55×10¹³/cm². The oxygen vacancy concentration refers to the number of oxygen vacancies per unit area.

The gate 250 is provided on the ferroelectric layer 240. The gate 250 may be disposed opposite to the channel layer 215 of the substrate 210. The gate 250 may include, for example, a conductive metal.

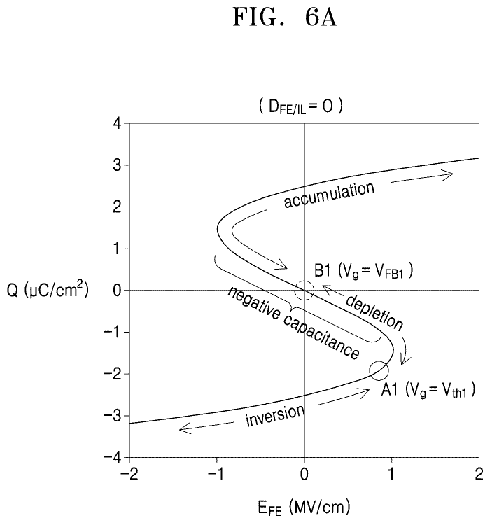

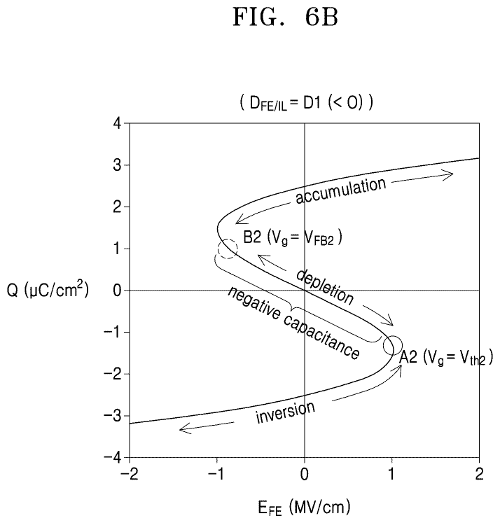

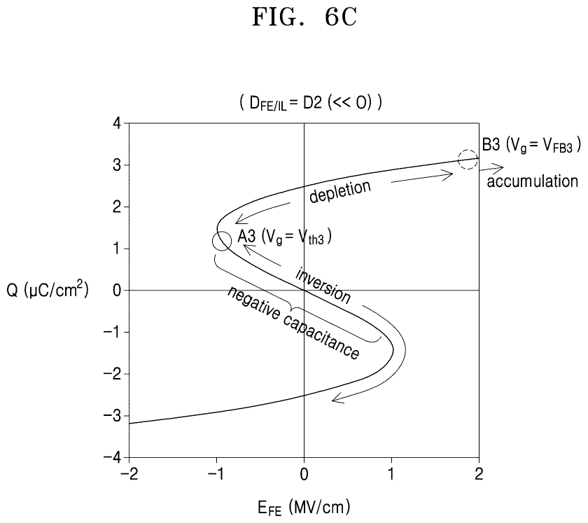

FIGS. 6A through 6C illustrate a correlation between a state of the semiconductor device of FIG. 5 and a negative capacitance region according to a charge density D_{FE/IL} of a fixed charge region in the semiconductor device of FIG. 5. A case where the semiconductor device 200 of FIG. 5 is a semiconductor device of a PMOS structure will now be described.

FIG. 6A illustrates a correlation between a state of the semiconductor device 200 and a negative capacitance region when the charge density D_{FE/IL} of the fixed charge region 270 is “0”, through a Q-E_{FE} graph of an “S” curved shape of ferroelectrics. This case is the same as the case of the semiconductor device 100 of FIG. 1 having no fixed charge layers 270.

Referring to FIG. 6A, the negative capacitance effect is generated when the semiconductor device 200 is in an accumulation state and a depletion state. In FIG. 6A, a point “A1” indicates a location of a first threshold voltage Vₜₕ₁, and a point “B1” indicates a location of a first planarization voltage V_{FB1}.

FIG. 6B illustrates a correlation between a state of the semiconductor device 200 and a negative capacitance region when the charge density DFE/IL of the fixed charge region 270 is “D1(<0)”, through a Q-EFE graph of an “S” curved shape of ferroelectrics.

Referring to FIG. 6B, the negative capacitance effect is generated when the semiconductor device 200 is in a depletion state. In FIG. 6B, a point “A2” indicates a location of a second threshold voltage Vₜₕ₂, and a point “B2” indicates a location of a second planarization voltage V_{FB2}.

FIG. 6C illustrates a correlation between a state of the semiconductor device 200 and a negative capacitance region when the charge density DFE/IL of the fixed charge region 270 is “D2(«0)”, which is a greater negative (−) value than D1, through a Q-EFE graph of an “S” curved shape of ferroelectrics.

Referring to FIG. 6C, the negative capacitance effect is generated when the semiconductor device 200 is in an inversion state. In FIG. 6C, a point “A3” indicates a location of a third threshold voltage Vₜₕ₃, and a point “B3” indicates a location of a third planarization voltage V_{FB3}.

As described above, the semiconductor device 200 of FIG. 5 may adjust the negative capacitance region by changing the charge density of the fixed charge region 270, and thus may generate a negative capacitance effect when the semiconductor device 200 is in a desired state. For example, as shown in FIG. 6C, the negative capacitance effect may be generated in an inversion state of the semiconductor device 200. In this case, voltage amplification may be maximized, and thus performance of the semiconductor device 200 may be more improved.

As a result of measuring the operating voltage of a ferroelectric (Hf) according to the charge density of the fixed charge region 270 in the semiconductor device 200 of a PMOS structure shown in FIG. 5, it was found that a negative capacitance effect in the inversion state was maximized in a −1.5 82 C/cm² to −1.0μC/cm² range of the charge density of the fixed charge region 270 and, thus, the performance of the semiconductor device 200 was maximized. It was also found that, as the charge density deviates from the −1.5 μC/cm² to −1.0 μC/cm² range, the performance of the semiconductor device 200 gradually deteriorated, and that the negative capacitance effect did not occur when the charge density is less than or equal to −5.0 μC/cm².

A case where the fixed charge region 270 has a negative (−) charge density to generate the negative capacitance effect in an inversion state of the semiconductor device 200 when the semiconductor device 200 is a semiconductor device of a PMOS structure has been described with reference to FIGS. 6A through 6C. When the semiconductor device 200 is a semiconductor device of an NMOS structure, the fixed charge region 270 has a positive (+) charge density to generate the negative capacitance effect in an inversion state of the semiconductor device 200. For example, in a semiconductor device of an NMOS structure, the fixed charge region 270 may have a charge density greater than 0 and less than +5 μC/cm², and, in a semiconductor device of a PMOS structure, the fixed charge region 270 may have a charge density greater than −5 μC/cm² and less than 0.

Referring to FIGS. 6A through 6C, as the charge density of the fixed charge region 270 changes from “0” to “D2”, a threshold voltage of the semiconductor device 200 changes from “Vₜₕ₁” to “Vₜₕ₃”. In this case, when a work function of the gate 250 is adjusted, the threshold voltage of the semiconductor device 200 may be controlled to have a desired value. In other words, when work function of the gate 250 is adjusted, a band alignment between a gate metal and ferroelectrics is achieved by an interfacial dipole, and thus the threshold voltage of the semiconductor device 200 may be controlled to have a desired value. Thus, even when the charge density of the fixed charge region 270 changes, the threshold voltage of the semiconductor device 200 may be constantly maintained as a desired value by adjusting the work function of the gate 250.

As described above, the semiconductor device 200 according to an embodiment may adjust the negative capacitance region according to a state of the semiconductor device 200 by changing the charge density of the fixed charge region 270. For example, voltage amplification may be maximized by generating the negative capacitance effect in an inversion state of the semiconductor device 200 by using the fixed charge region 270, and thus performance of the semiconductor device 200 may be more improved.

Because the threshold voltage of the semiconductor device 200 may be controlled by adjusting the work function of the gate 250, the threshold voltage of the semiconductor device 200 may be constantly maintained as a desired value by adjusting the work function of the gate 250. The remnant polarization Pr or the coersive electric field Ec of ferroelectrics is increased by adjusting a method of depositing ferroelectrics or a method of annealing ferroelectrics, leading to an improvement in the negative capacitance effect.

The charge density in the fixed charge region 270 may be calculated, for example, using a measurement method using an S-curve, which represents a correlation between the charge Q of the ferroelectric and the electric field E_{FE} applied to the ferroelectric. The measurement method using the S-curve is well known to those skilled in the art, and is described in detail in, for example, Michael Hoffmann et al: “Unveiling the double-well energy landscape in a ferroelectric layer”, Supplementary Information, Nature (2019).

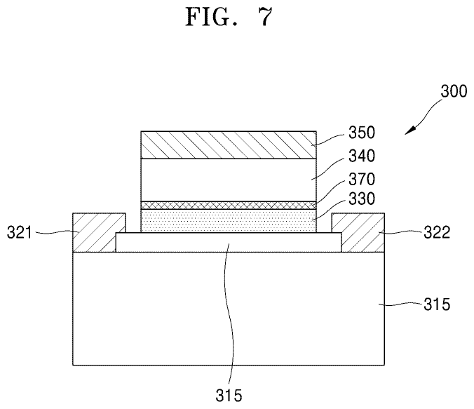

FIG. 7 is a schematic cross-sectional view of a semiconductor device 300 according to another embodiment. The semiconductor device 300 of FIG. 7 is similar to the semiconductor device 200 of FIG. 5 except that a channel layer 315 is provided separately from a substrate 310.

Referring to FIG. 7, the semiconductor device 300 includes a substrate 310, a channel layer 315, an insulation layer 330, a fixed charge region 370, a ferroelectric layer 340, and a gate 350. The channel layer 315 may be provided in an upper portion of the substrate 310 that faces the gate 350, and a source 321 and a drain 322 may be provided on both sides of the channel layer 315, respectively.

The substrate 310 may include, for example, Si, Ge, SiGe, or Group III-V semiconductor, but embodiments are not limited thereto. The channel layer 315 is provided on an upper surface of the substrate 310. The channel layer 315 may be provided as a material layer separate from the substrate 310. The channel layer 315 may include, for example, Si, Ge, SiGe, or Group III-V semiconductor. The channel layer 315 may include, for example, at least one of an oxide semiconductor, a nitride semiconductor, an oxynitride semiconductor, a 2D material, quantum dots, and an organic semiconductor. The oxide semiconductor may include, for example, InGaZnO, the 2D material may include, for example, transition metal dichalcogenide (TMD) or graphene, and the quantum dots may include colloidal QDs, a nanocrystal structure, or the like. However, this is merely an example, and embodiments of the present disclosure are not limited thereto.

A source 321 and a drain 322 may be formed on both sides of the channel layer 315, respectively. The source 321 may be provided to be connected to one side of the channel layer 315, and the drain 322 may be provided to be connected to the other side of the channel layer 315. The source and drain 321 and 322 may include a conductive material. The insulation layer 330, the fixed charge region 370, the ferroelectric layer 340, and the gate 350 are sequentially stacked on the channel layer 315. This has been described above, and thus a detailed description thereof will be omitted.

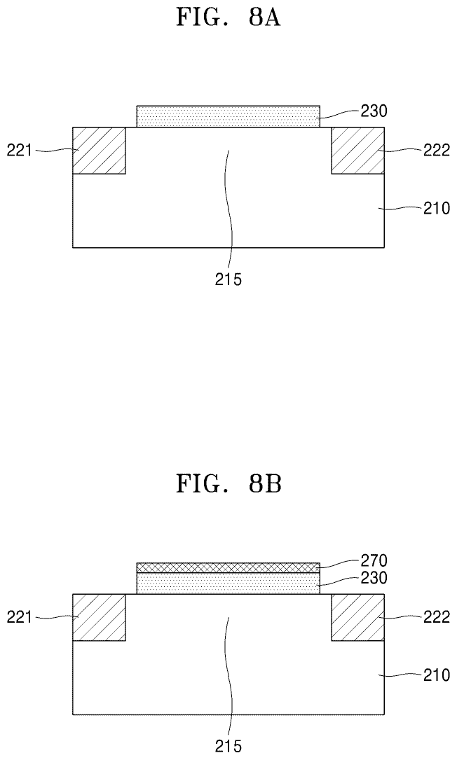

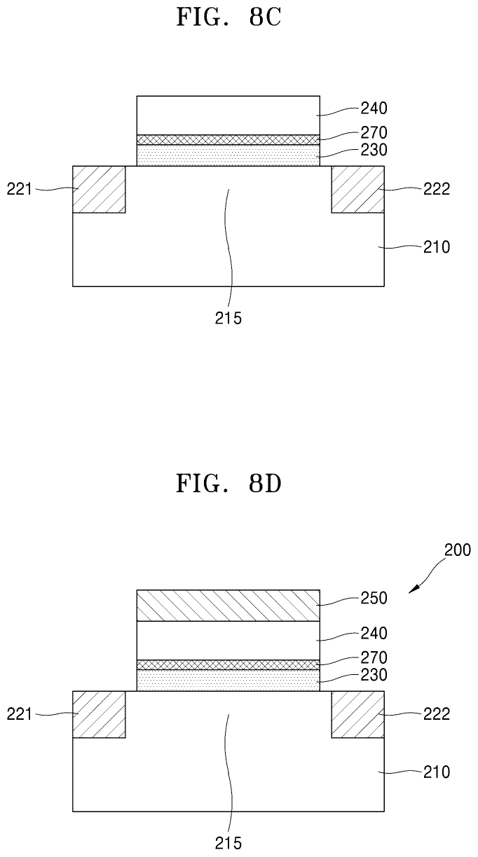

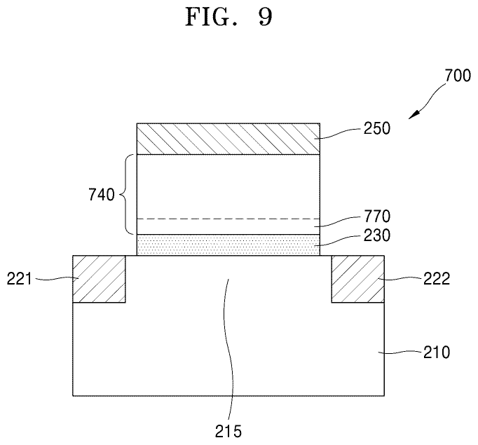

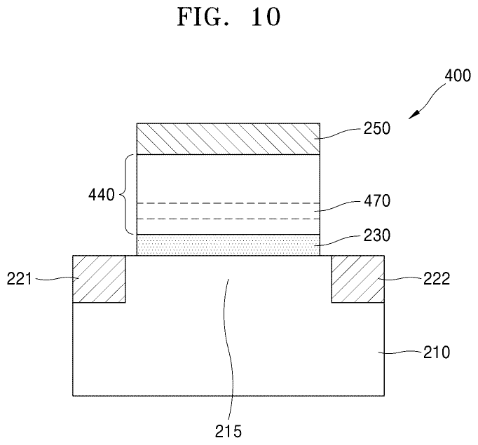

FIGS. 8A through 8D are views for explaining a method of a manufacturing the semiconductor device 200, according to an embodiment.

Referring to FIG. 8A, the substrate 210 on which the source and drain 221 and 222 and the channel layer 215 are provided is prepared for. The source 221 and the drain 222 may be formed by implanting/doping impurities into different regions of the substrate 210, and a region of the substrate 210 between the source 221 and the drain 222 may be defined as the channel layer 215.

The substrate 210 and the channel layer 215 may include Si. However, this is merely an example, and the substrate 210 and the channel layer 215 may include, for example, Ge, SiGe, or Group III-V semiconductor. However, embodiments of the present disclosure are not limited thereto, and the material of the substrate 210 may vary. The time point when the source 221 and the drain 222 are formed may vary. For example, after the gate 250 of FIG. 8D, which will be described later, is formed, the source 221 and the drain 222 may be formed within the substrate 210.

As shown in FIG. 7, the channel layer 315 may be a material layer separate from the substrate 310 and thus may be formed on the upper surface of the substrate 310. In this case, the material composition of the channel layer 315 may vary. For example, the channel layer 315 may include, for example, at least one of Si, Ge, SiGe, a Group III-V semiconductor, an oxide semiconductor, a nitride semiconductor, an oxynitride semiconductor, a 2D material, quantum dots, and an organic semiconductor. The oxide semiconductor may include, for example, InGaZnO, the 2D material may include, for example, TMD or graphene, and the quantum dots may include colloidal QDs, a nanocrystal structure, or the like. However, embodiments of the present invention are not limited thereto.

Next, the insulation layer 230 is formed on an upper surface of the channel layer 215 of the substrate 210. The insulation layer 230 may be formed by depositing a predetermined insulating material on the upper surface of the channel layer 215 of the substrate 210 by using, for example, Atomic Layer Deposition (ALD) or Chemical Vapor Deposition (CVD). The insulation layer 230 may include a paraelectric material or a high-k material. For example, the insulation layer 230 may include silicon oxide, silicon nitride, aluminum oxide, hafnium oxide, or zirconium oxide or may include a 2D insulator such as h-BN. However, this is merely an example.

Referring to FIG. 8B, the fixed charge region 270 having charges of predetermined polarity is formed on an upper surface of the insulation layer 230. The fixed charge region 270 may be formed to have a charge density that generates the negative capacitance effect in an inversion state of the channel layer 315.

In a semiconductor device of an NMOS structure, the fixed charge region 270 may have a positive (+) charge density, and, in a semiconductor device of a PMOS structure, the fixed charge region 270 may have a negative (−) charge density. For example, in a semiconductor device of a PMOS structure, the fixed charge region 270 may have a negative (−) charge density greater than −5 μC/cm² and less than 0, and, in a semiconductor device of an NMOS structure, the fixed charge region 270 may have a positive (+) charge density greater than 0 and less than +5 μC/cm².

The fixed charge region 270 may be formed by depositing a dopant including charges of a predetermined polarity on a surface of the insulation layer 230. The dopant may include at least one selected from, for example, Al, P, Ca, Sc, V, Cr, Sr, Y, Nb, Mo, Tm, Yb, Lu, Ta, W, B, and Mg. However, embodiments of the present disclosure are not limited thereto. The fixed charge region 270 may be formed by processing the upper surface of the insulation layer 230. For example, when the upper surface of the insulation layer 230 is damaged by plasma, ion beams, or the like, an oxygen vacancy is formed on the upper surface of the insulation layer 230, and thus the fixed charge region 270 including charges of a predetermined polarity may be formed.

Referring to FIG. 8C, the ferroelectric layer 240 is formed on the fixed charge region 270. The ferroelectric layer 240 may be formed by depositing a predetermined dielectric material on the fixed charge region 270 by using ALD or CVD and then annealing the dielectric material.

The ferroelectric layer 240 may include ferroelectrics, such as a fluorite-based material, a perovskite, aluminum nitride, or magnesium oxide. The perovskite may include, for example, PZT, BaTiO₃, or PbTiO₃. The fluorite-based material may include, for example, at least one oxide selected from Hf, Si, Al, Zr, Y, La, Gd, and Sr.

For example, the ferroelectric layer 240 may include at least one of HfO, ZrO, and HfZrO. However, the aforementioned materials are only an example, and various other materials may be used to form the ferroelectric layer 240.

Referring to FIG. 8D, the semiconductor device 200 is completed by forming the gate 250 on the ferroelectric layer 240. The gate 250 may be formed by depositing a predetermined conductive metal on the ferroelectric layer 240 by using, for example, ALD, CVD, or Physical Vapor Deposition (PVD) and then annealing the deposited predetermined conductive metal.

Although it has been described above that annealing is performed both when forming the ferroelectric layer 240 and when forming the gate 250, annealing is performed after a predetermined dielectric material and a predetermined conductive metal are deposited on the fixed charge region 270, and thus the ferroelectric layer 240 and the gate 250 may be simultaneously formed.

As described above, an operation of adjusting the work function of the gate 250 may be further performed after the semiconductor device 200 is completed. As described above, when the work function of the gate 250 is adjusted, the threshold voltage of the semiconductor device 200 may be controlled to have a desired value.

In the semiconductor device 200 shown in FIG. 5, a case where the fixed charge region 270 is provided as a separate independent layer at an interface between the ferroelectric layer 240 and the insulation layer 230 has been described. However, a fixed charge region may be provided to be included in a ferroelectric layer, as will be described later.

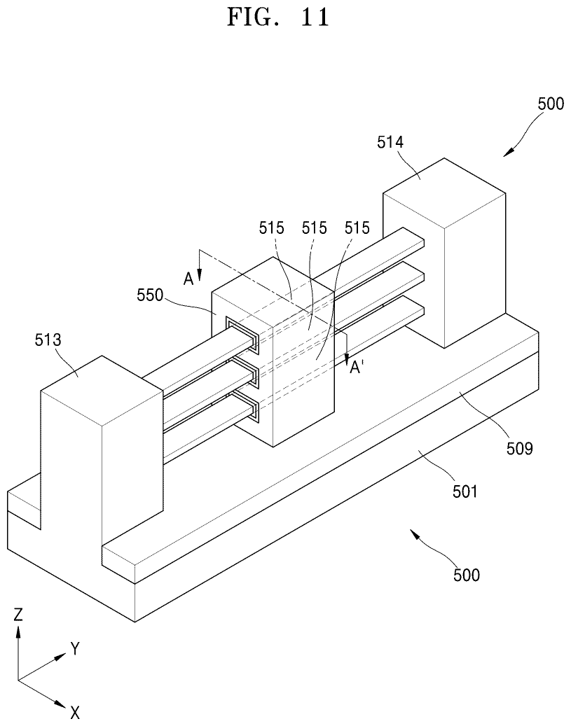

FIG. 9 is a schematic cross-sectional view of a semiconductor device 700 according to another embodiment. Differences from the above-described embodiment will now be mainly described.

Referring to FIG. 9, the insulation layer 230, a ferroelectric layer 740, and the gate 250 are sequentially provided on the channel layer 215. A fixed charge region 770 is provided on the ferroelectric layer 740. The fixed charge region 770 may be disposed on a lower surface of the ferroelectric layer 740. In other words, the fixed charge region 770 may be formed on an interface of the ferroelectric layer 740 in contact with the insulation layer 230.

The ferroelectric layer 740 may include a predetermined dopant. The dopant may include at least one selected from, for example, Al, P, Ca, Sc, V, Cr, Sr, Y, Nb, Mo, Tm, Yb, Lu, Ta, and W, but embodiments are not limited thereto. The ferroelectric layer 740 may have a dopant concentration gradient in its thickness direction. In this case, the fixed charge region 770 may be defined by a region in the ferroelectric layer 740 where the concentration of the dopant collects (i.e., a dopant concentration collecting region).

An absolute value of the charge density in the fixed charge region 770 may be greater than 0 and less than 5 μC/cm². When this absolute value of the charge density is converted to a dopant concentration, the dopant concentration in the fixed charge region 770, which is defined as the dopant concentration collecting region, may be greater than 0 and less than 3.1×10¹³/cm². A thickness of the fixed charge region 770 defined as the dopant concentration collecting region may be approximately 1 Å to 10 Å (e.g., 1 Å to 3 Å). However, embodiments are not limited thereto.

The ferroelectric layer 740 may include oxygen vacancy. The ferroelectric layer 740 may have an oxygen vacancy concentration gradient in its thickness direction. In this case, the fixed charge region 770 may be defined by a region where the concentration of the oxygen vacancy collects (i.e., an oxygen vacancy concentration collecting region).

The absolute value of the charge density in the fixed charge region 770 may be greater than 0 and less than 5 μC/cm². When this absolute value of the charge density is converted to an oxygen vacancy concentration, the oxygen vacancy concentration in the fixed charge region 770, which is defined as the oxygen vacancy concentration collecting region, may be greater than 0 and less than 1.55×10¹³/cm². A thickness of the fixed charge region 770 defined as the oxygen vacancy concentration collecting region may be approximately 1 Å to 10 Å (e.g., 1 Å to 5 Å or 1 Å to 3 Å). However, embodiments are not limited thereto.

A case where the fixed charge region 770 is provided on an interface of the ferroelectric layer 740 in contact with the insulation layer 230 has been described above. However, embodiments are not limited thereto. As will be described later, a fixed charge region may be provided within a ferroelectric layer.

FIG. 10 is a schematic cross-sectional view of a semiconductor device 400 according to another embodiment. Differences from the above-described embodiment will now be mainly described.

Referring to FIG. 10, the insulation layer 230, a ferroelectric layer 440, and the gate 250 are sequentially provided on the channel layer 215. A fixed charge region 470 is provided within the ferroelectric layer 440.

The ferroelectric layer 440 may include a predetermined dopant. The ferroelectric layer 440 may have a dopant concentration gradient in its thickness direction. In this case, the fixed charge region 470 may be defined by a region in the ferroelectric layer 440 where the concentration of the dopant collects (i.e., a dopant concentration collecting region). The dopant concentration in the fixed charge region 470, which is defined as the dopant concentration collecting region, may be greater than 0 and less than 3.1×10¹³/cm². A thickness of the fixed charge region 470 defined as the dopant concentration collecting region may be approximately 1 Å to 10 Å (e.g., 1 Å to 3 Å). However, embodiments are not limited thereto.

The ferroelectric layer 440 may include oxygen vacancy. The ferroelectric layer 440 may have an oxygen vacancy concentration gradient in its thickness direction. In this case, the fixed charge region 470 may be defined by a region where the concentration of the oxygen vacancy collects (i.e., an oxygen vacancy concentration collecting region). The oxygen vacancy concentration in the fixed charge region 470, which is defined as the oxygen vacancy concentration collecting region, may be greater than 0 and less than 1.55×10¹³/cm². A thickness of the fixed charge region 470 defined as the oxygen vacancy concentration collecting region may be approximately 1 Å to 10 Å (e.g., 1 Å to 5 Å or 1 Å to 3 Å). However, embodiments are not limited thereto.

The fixed charge region 470 defined as the dopant concentration collecting region or the oxygen vacancy concentration collecting region may be provided inside the ferroelectric layer 440. In this case, the fixed charge region 470 may be formed adjacent to an interface between the ferroelectric layer 440 and the insulation layer 230.

In detail, when the fixed charge region 470 is disposed inside the ferroelectric layer 440, a location of the fixed charge region 470 capable of generating a negative capacitance effect in the inversion state may be calculated as follows.

For example, assuming that a controllable charge density in the channel layer 215 including Si is 3 μC/cm², a location of the fixed charge region 470 with a charge density of 5 μC/cm² capable of controlling the charge density in the channel layer 215 by 3 μC/cm², that is, a maximum distance t of the fixed charge region 470 away from from the interface between the insulating layer 230 and the ferroelectric layer 440, may be calculated using the following Equation 1.

5 μC/cm²×(T_{FE-}t)=3μC/cm²×T_{FE . . .} Equation 1

It may be seen from Equation 1 that t=0.4×T_{FE}, and, accordingly, it may be seen that, when the fixed charge region 470 is located at a position corresponding to 40% of the thickness T_{FE} of the ferroelectric layer 440 from the interface between the insulation layer 230 and the ferroelectric layer 440, the charge density in the channel layer 215 may be controlled by 3 μC/cm². For example, when the thickness T_{FE} of the ferroelectric layer 440 is 15 Å, the fixed charge region 470 may be located at a position that is 6 Å away from the interface between the insulation layer 230 and the ferroelectric layer 440.

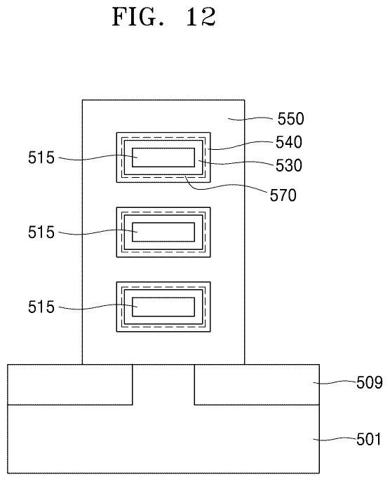

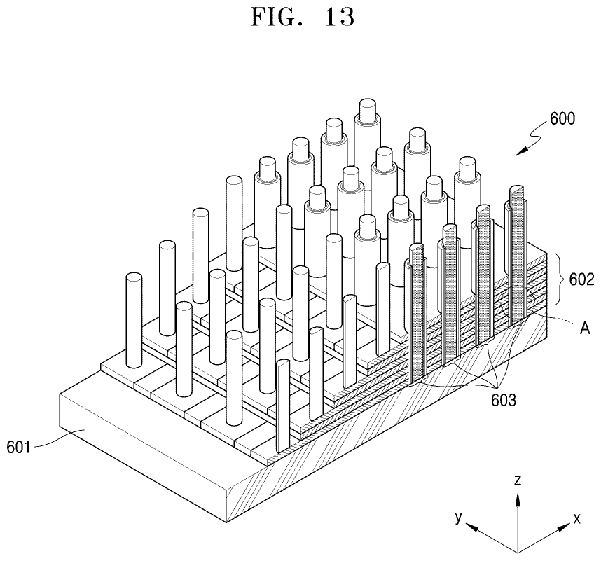

FIG. 11 is a perspective view of a semiconductor device 500 according to another embodiment, and FIG. 12 is a cross-sectional view taken along line A-A′ of FIG. 11. The semiconductor device 500 shown in FIGS. 11 and 12 is formed in a three-dimensional (3D) structure in which a gate 550 surrounds respective four sides of channel layers 515. The semiconductor device 500 may be, for example, a Gate-All-Around Field Effect Transistor (GAAFET) or a Multibridge-Channel Field Effect Transistor (MBCFET).

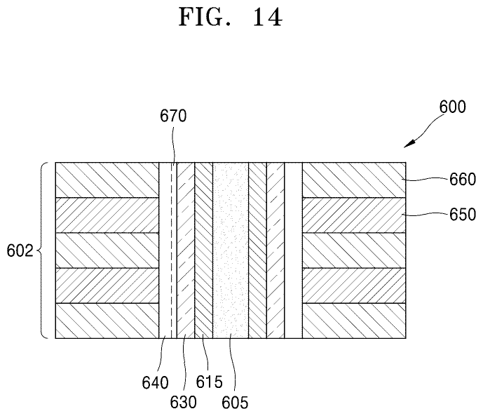

Referring to FIGS. 11 and 12, a first source/drain region 513 and a second source/drain region 514 are provided to each protrude in a Z axis direction from an upper surface of a substrate 501 on which an insulation layer 509 is formed. A plurality of channel layers 515 are provided between the first source/drain region 513 and the second source/drain region 514 to be each spaced apart from the upper surface of the substrate 501 and extend in a Y axis direction. Each of the channel layers 515 is provided such that its four sides are surrounded by a gate insulation layer 530, and the gate insulation layer 530 is provided to be surrounded by a ferroelectric layer 540. A fixed charge region 570 is provided on an interface between the insulation layer 530 and the ferroelectric layer 540 or within the ferroelectric layer 540. Because the fixed charge region 570 has been described above, a detailed description thereof will be omitted. When the semiconductor device 500 is a logic semiconductor device, the ferroelectric layer 540 may be formed to have a thickness of approximately 3 nm or less. The gate layer 550 is provided to surround the ferroelectric layer 540. FIG. 13 is a perspective view of a semiconductor device 600 according to another embodiment, and FIG. 14 is a magnified cross-sectional view of a portion ‘A’ of FIG. 13. The semiconductor device 600 shown in FIG. 13 may be a memory cell string of a 3D NAND (e.g., VNAND) or a 3D FeFET memory device.

Referring to FIGS. 13 and 14, the semiconductor device 600 includes a stacked structure 602 in which a plurality of insulation layers 660 and a plurality of gates 650 are alternately and repeatedly stacked on a substrate 601. In detail, each of the plurality of insulation layers 660 and the plurality of gate electrodes 650 extends along an X-Y plane on the substrate 601. The stacked structure 602 may be formed by repeatedly and alternately stacking the plurality of insulation layers 660 and the plurality of gate electrodes 650 in the Z axis direction.

A plurality of channel holes are formed to pass through the stacked structure 602, and a ferroelectric layer 640, a gate insulation layer 630, and a channel layer 615 are sequentially arranged in a concentric circle shape inside each of the channel holes to thereby form a memory cell string 603. The ferroelectric layer 640 may be formed to have a thickness of approximately 10 nm to 30 nm (e.g., 10 nm to 20 nm, or 20 nm to 30 nm). The interior of each channel hole may be filled with a dielectric filler 605. The memory cell string 603 is surrounded by the insulation layers 660 and the gates 650. The ferroelectric layer 640, the gate insulation layer 630, and the channel layer 615 may all extend in the Z axis direction and intersect the insulation layers 660 and the gates 650. A plurality of memory cell strings 603 are formed, and may be arranged on the substrate 601 in a 2D manner.

A fixed charge region 670 is provided on an interface between the gate insulation layer 630 and the ferroelectric layer 640 or within the ferroelectric layer 640. Because the fixed charge region 670 has been described above, a detailed description thereof will be omitted.

s described above, a semiconductor device according to an embodiment may adjust a negative capacitance region according to a state of the semiconductor device by adjusting the charge density of a fixed charge region. In other words, voltage amplification may be maximized by generating a negative capacitance effect in an inversion state of the semiconductor device by using the fixed charge region having a predetermined charge density, and thus performance of the semiconductor device may be more improved.

Because the threshold voltage of the semiconductor device may be controlled by adjusting the work function of a gate, the threshold voltage of the semiconductor device may be constantly maintained as a desired value by adjusting the work function of the gate. The remnant polarization Pr or the coersive electric field Ec of ferroelectrics is increased by adjusting a method of depositing ferroelectrics or a method of annealing ferroelectrics, leading to an improvement in the negative capacitance effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a substrate on which a channel layer is provided;
an insulation layer provided on the substrate;
a ferroelectric layer provided on the insulation layer;
a fixed charge region provided in the ferroelectric layer and containing charges of a predetermined polarity; and
a gate provided on the ferroelectric layer,
wherein an absolute value of a charge density in the fixed charge region is greater than 0 and less than 5 μC/cm².

2. The semiconductor device of claim 1, wherein
the absolute value of the charge density in the fixed charge region is greater than 2 μC/cm² and less than 3 μC/cm².

3. The semiconductor device of claim 1, wherein a thickness of the fixed charge region is 1 Å to 10 Å.

4. The semiconductor device of claim 1, wherein the ferroelectric layer has a dopant concentration gradient in its thickness direction, and the fixed charge region is defined by a dopant concentration collecting region in the ferroelectric layer.

5. The semiconductor device of claim 4, wherein the dopant includes at least one selected from Al, P, Ca, Sc, V, Cr, Sr, Y, Nb, Mo, Tm, Yb, Lu, Ta, W, B, and Mg.

6. The semiconductor device of claim 1, wherein the ferroelectric layer has an oxygen vacancy concentration gradient in its thickness direction, and the fixed charge region is defined by an oxygen vacancy concentration collecting region in the ferroelectric layer.

7. The semiconductor device of claim 1, wherein the fixed charge region is disposed on an interface between the ferroelectric layer and the insulation layer.

8. The semiconductor device of claim 1, wherein the fixed charge region is disposed within the ferroelectric layer.

9. The semiconductor device of claim 8, wherein the fixed charge region is located adjacent to an interface between the ferroelectric layer and the insulation layer.

10. The semiconductor device of claim 1, wherein the fixed charge region has a negative (−) charge density in a semiconductor device of a PMOS structure, and has a positive (+) charge density in a semiconductor device of an NMOS structure.

11. The semiconductor device of claim 1, wherein the ferroelectric layer includes a fluorite-based material, a perovskite, aluminum nitride, or magnesium oxide.

12. The semiconductor device of claim 1, wherein the channel layer includes at least one of Si, Ge, SiGe, a Groups III-V semiconductor, an oxide semiconductor, a nitride semiconductor, an oxynitride semiconductor, a two-dimensional (2D) material, quantum dots, and an organic semiconductor.

13. The semiconductor device of claim 1, wherein a threshold voltage of the semiconductor device is controlled by adjusting a work function of the gate.

14. A semiconductor device comprising:
a substrate on which a channel layer is provided;
an insulation layer provided on the substrate;
a ferroelectric layer provided on the insulation layer;
a dopant concentration collecting region provided in the ferroelectric layer; and
a gate provided on the ferroelectric layer,
wherein a dopant concentration in the dopant concentration collecting region is greater than 0 and less than 3.1×10¹³/cm².

15. The semiconductor device of claim 14, wherein the ferroelectric layer has a dopant concentration gradient in its thickness direction.

16. The semiconductor device of claim 14, wherein the dopant includes at least one selected from Al, P, Ca, Sc, V, Cr, Sr, Y, Nb, Mo, Tm, Yb, Lu, Ta, W, B, and Mg.

17. The semiconductor device of claim 14, wherein the dopant concentration collecting region is disposed on an interface between the ferroelectric layer and the insulation layer or within the ferroelectric layer.

18. A semiconductor device comprising:
a substrate on which a channel layer is provided;
an insulation layer provided on the substrate;
a ferroelectric layer provided on the insulation layer;
an oxygen vacancy concentration collecting region provided in the ferroelectric layer; and
a gate provided on the ferroelectric layer,
wherein an oxygen vacancy concentration in the oxygen vacancy concentration collecting region is greater than 0 and less than 1.55×10¹³/cm².

19. The semiconductor device of claim 18, wherein the ferroelectric layer has an oxygen vacancy concentration gradient in its thickness direction.

20. The semiconductor device of claim 18, wherein the oxygen vacancy concentration collecting region is disposed on an interface between the ferroelectric layer and the insulation layer or within the ferroelectric layer.
